(19) United States
(12) Patent Application Publication
(10) Pub. No.: US 2026/0341069 A1
(43) Pub. Date: Oct. 29, 2026

(54) SIGNAL LINE GROUP DETECTION METHOD AND APPARATUS, AND MEDIUM

(71) Applicants: Hefei BOE Vision-Electronic Technology Co.,Ltd., Hefei, Anhui (CN); BOE Technology Group Co., Ltd., Beijing (CN)

(72) Inventors: Yu ZHANG, Beijing (CN); Lei SHI, Beijing (CN); Qiang LUO, Beijing (CN); Zhangjin NI, Beijing (CN); Yuliang QIAN, Beijing (CN); Chaolei LIU, Beijing (CN); Zhongcai DONG, Beijing (CN); Lei GUO, Beijing (CN); Gang SUN, Beijing (CN); Hang GAO, Beijing (CN)

(21) Appl. No.: 18/995,371

(22) PCT Filed: May 24, 2023
(86) PCT No.: PCT/CN2023/096124

§ 371 Date: Jan. 16, 2025

(51) Int. Cl. G06V 30/422

(52) U.S. Cl. CPC G06V 30/422

(57) ABSTRACT

The present disclosure relates to the field of the computer technology and discloses a method and device for detecting a signal line group, and a medium. The method is as follows: segmented groups are determined based on segmented lines in two signal lines in the signal line group; usually, each signal line in the signal line group includes a plurality of segmented lines, so that there are a plurality of segmented groups; each of the segmented groups includes two segmented lines, the two segmented lines belong to different signal lines, and the two signal lines are configured to transmit two signals having the same amplitude and opposite phases; and a detection result for the signal line group is determined based on a difference between lengths of the two segmented lines in the segmented group.

### CROSS REFERENCE TO RELATED APPLICATION

The present application is a National Stage of International Application No. PCT/CN2023/096124, filed on May 24, 2023, which is incorporated by reference in its entirety herein.

### TECHNICAL FIELD

The present disclosure relates to the field of computer technology, and provides a method and device for detecting a signal line group, and a medium.

### BACKGROUND

In the related technology, when confirming whether two segmented lines (assuming that there are lines P and N) in the area corresponding to the differential signal lines and the entire differential signal lines satisfy the preset equal length requirement, it is necessary to manually click and select the above segmented lines in a drawing software, manually calculate the lengths of the two segmented lines P and N based on the coordinates of the two endpoints of the above segmented lines, and then compare the above lengths to determine whether they are equal, which is a cumbersome process. In addition, on the basis of determining the lengths, it is necessary to further check whether the electrical connection is corrected, which is time-consuming and laborious.

### SUMMARY

Embodiments of the present disclosure provide a method and device for detecting a signal line group, and a medium, for quickly and accurately determining whether the detection result for the signal line group is qualified.

The specific technical solution according to the present disclosure is as follows.

In a first aspect, an embodiment of the present disclosure provides a method for detecting a signal line group, including: determining segmented groups based on segmented lines in two signal lines in the signal line group; where each of the segmented groups includes two segmented lines; the two segmented lines belong to different signal lines; and the two signal lines are configured to transmit two signals having the same amplitude and opposite phases; and determining a detection result for the signal line group based on a difference between lengths of the two segmented lines in the segmented group.

Optionally, the determining a detection result for the signal line group based on a difference between lengths of the two segmented lines in the segmented group, includes: determining that the segmented detection result for the signal line group is qualified in a case that the difference between the lengths of the two segmented lines in each of the segmented groups is less than a corresponding length threshold.

Optionally, the determining a detection result for the signal line group based on a difference between lengths of the two segmented lines in the segmented group, includes: in a case that a sum of lengths of the segmented lines belonging to the same one signal line is less than a preset sum-of-lengths threshold, and a difference between the sums of lengths belonging to the same one signal line group is less than a total length threshold, determining that the total length detection result for the signal line group is qualified.

Optionally, the segmented groups are in the same one layer or different layers of a printed circuit board, and length thresholds corresponding to two segmented lines in segmented groups in different layers of the printed circuit board have different values.

Optionally, the length of each of the segmented lines in the segmented group is automatically read from a drawing software, and the drawing software is configured to draw the signal line group in a printed circuit board.

Optionally, whether two segmented lines belong to the same one segmented group is determined by: determining, based on names of the signal lines corresponding to any two segmented lines and the signal directions of signals in the signal lines, whether the two segmented lines belong to the same one segmented group.

Optionally, the determining, based on names of the signal lines corresponding to any two segmented lines and the signal directions of signals in the signal lines, whether the two segmented lines belong to the same one segmented group, includes: determining the signal lines corresponding to any two segmented lines in the drawing software; and in a case that the names of the signal lines corresponding to any two segmented lines are the same, and the signals of any two segmented lines have the same signal direction in the signal lines, determining that the any two segmented lines belong to the same segmented group.

Optionally, before determining a detection result for the signal line group based on a difference between lengths of the two segmented lines in the segmented group, the method further includes: determining whether an electrical connection performance of each of the signal lines in the signal line group is qualified.

Optionally, the determining whether an electrical connection performance of each of the signal lines in the signal line group is qualified, includes: arranging the segmented lines of each of the signal lines in the signal line group in sequence based on a signal direction of a signal for transmission by the signal line group; and determining whether the electrical connection performance of the signal line is qualified based on that whether the segmented lines after being arranged form a connected signal line.

Optionally, whether the segmented lines of each of the signal lines form a connected signal line is determined by: obtaining coordinates of endpoints of the segmented lines of each of the signal lines, where the coordinates do not include coordinates of the initial endpoint and the termination endpoint of the signal line; and the endpoints are configured to indicate connection points of electrical symbols corresponding to the segmented lines in the printed circuit board; establishing a coordinate set based on the coordinates of the endpoints; and determining, based on a distance between the coordinates in the coordinate set, whether the segmented lines of the signal line after being arranged form a connected signal line.

Optionally, the determining, based on a distance between the coordinates in the coordinate set, whether the segmented lines of the signal line after being arranged form a connected signal line, includes: searching in the coordinate set for matching coordinates whose distance from target coordinates is not greater than a coordinate threshold, where the target coordinates are coordinates of any of the endpoints in the coordinate set; and determining, based on that the matching coordinates exist or no matching coordinates exist, whether the segmented lines of the signal line after being arranged form a connected signal line.

Optionally, the determining, based on that the matching coordinates exist or no matching coordinates exist, whether the segmented lines of the signal line after being arranged form a connected signal line, includes: in a case that the matching coordinates exist, determining the segmented lines of the signal line after being arranged form a connected signal line; and in a case that no matching coordinates exist, determining the segmented lines of the signal line after being arranged do not form a connected signal line.

Optionally, the searching in the coordinate set for matching coordinates whose distance from target coordinates is not greater than a coordinate threshold, includes: dividing the coordinates in the coordinate set into a plurality of subsets of different types based on the endpoints in the coordinate set; searching in the subset of the same type for the matching coordinates whose distance from the target coordinates is not greater than the coordinate threshold; and in a case that no matching coordinates are found in the subset of the same type, searching in the subsets of other types for the matching coordinates whose distance from the target coordinates is not greater than the coordinate threshold.

Optionally, the plurality of subsets of different types include at least a pin subset, a via-hole subset, a surface-layer line subset and an inner-layer line subset.

In a second aspect, an embodiment of the present disclosure provides a device for detecting a signal line group, including: a determination unit, configured to determine segmented groups based on segmented lines in two signal lines in the signal line group; where each of the segmented groups includes two segmented lines; the two segmented lines belong to different signal lines; and the two signal lines are configured to transmit two signals having the same amplitude and opposite phases; and a detection unit, configured to determine a detection result for the signal line group based on a difference between lengths of the two segmented lines in the segmented group.

In a third aspect, a device for detecting a signal line group includes: a memory, configured to store executable instructions; and a processor, configured to read and execute the executable instructions stored in the memory, to implement any method in the first aspect.

In a fourth aspect, a computer-readable storage medium is provided, and instructions in the storage medium, when executed by a processor, cause the processor to execute any method in the first aspect.

The beneficial effects of the disclosure are as follows.

In summary, embodiments of the present disclosure provide a method and device for detecting a signal line group, and a medium. The method is as follows: segmented groups are determined based on segmented lines in two signal lines in the signal line group; usually, each signal line in the signal line group includes a plurality of segmented lines, so that there are a plurality of segmented groups; each of the segmented groups includes two segmented lines, the two segmented lines belong to different signal lines, and the two signal lines are configured to transmit two signals having the same amplitude and opposite phases; and a detection result for the signal line group is determined based on a difference between lengths of the two segmented lines in the segmented group, i.e., whether the detection result for the signal line group is qualified is quickly and accurately determined by comparing the differences corresponding to the segmented groups.

Other features and advantages of the present disclosure will be elaborated in the subsequent description, and will be partially apparent from the description or will be understood by implementation of the present disclosure. The objectives and other advantages of the present disclosure may be realized and obtained by the structure as particularly indicated in the description, the claims, and the accompanying drawings.

### BRIEF DESCRIPTION OF FIGURES

The accompanying drawings illustrated herein are used to provide the further understanding of the present disclosure and form a part of the present disclosure. The illustrative embodiments of the present disclosure and their descriptions are used to explain the present disclosure and do not constitute an undue limitation of the present disclosure. In the accompanying drawings.

FIG. 1 shows a schematic diagram of a signal line group according to an embodiment of the present disclosure.

FIG. 2 shows another schematic diagram of a signal line group according to an embodiment of the present disclosure.

FIG. 3 shows a schematic diagram of a signal line group having a plurality of segmented lengths after passing through different PCB layers according to an embodiment of the present disclosure.

FIG. 4 shows a schematic flow diagram of a method for detecting a signal line group according to an embodiment of the present disclosure.

FIG. 5 shows another schematic flow diagram of a method for detecting a signal line group according to an embodiment of the present disclosure.

FIG. 6 shows a schematic flow diagram of determining whether an electrical connection performance of a signal line is qualified based on segmented lines according to an embodiment of the present disclosure.

FIG. 7 shows a schematic flow diagram of determining whether an electrical connection performance of a signal line is qualified based on the connectivity of the segmented lines after being arranged according to an embodiment of the present disclosure.

FIG. 8 is a schematic diagram of a logic architecture of a device for detecting a signal line group according to an embodiment of the present disclosure.

FIG. 9 shows a schematic diagram of a physical architecture of a device for detecting a signal line group according to an embodiment of the present disclosure.

### DETAILED DESCRIPTION

In order to make the objects, technical solutions and advantages of the embodiments of the present disclosure clearer, the technical solutions of the present disclosure will be described clearly and completely in the following in conjunction with the accompanying drawings in the embodiments of the present disclosure. It is clear that the described embodiments are a part of the embodiments of the technical solutions of the present disclosure and not all of the embodiments. Based on the embodiments recorded in the present disclosure, all other embodiments obtained by a person of ordinary skill in the art without making creative labor fall within the scope of protection of the technical solutions of the present disclosure.

The terms “first”, “second” and the like in the specification and claims of the present disclosure and the above accompanying drawings are used to distinguish similar objects, and need not be used to describe a particular order or sequence. It should be understood that the data used may be interchanged, where appropriate, so that the embodiments of the present disclosure described herein can be implemented using an order other than those illustrated or described herein.

Preferred embodiments of the present disclosure are described in detail below in connection with the accompanying drawings.

It should be noted that the signal line group in the present disclosure typically refer to a differential signal line group. In some application scenarios, the above-described signal line group may also be a collection of other types of signal lines. Differential signals are a common signal form. Usually, the differential signals are transmitted on both signal lines, and the signals transmitted on the different signal lines have the same amplitude and opposite phases. In embodiments of the present disclosure, the two signal lines described above for transmitting differential signals are referred to as one signal line group.

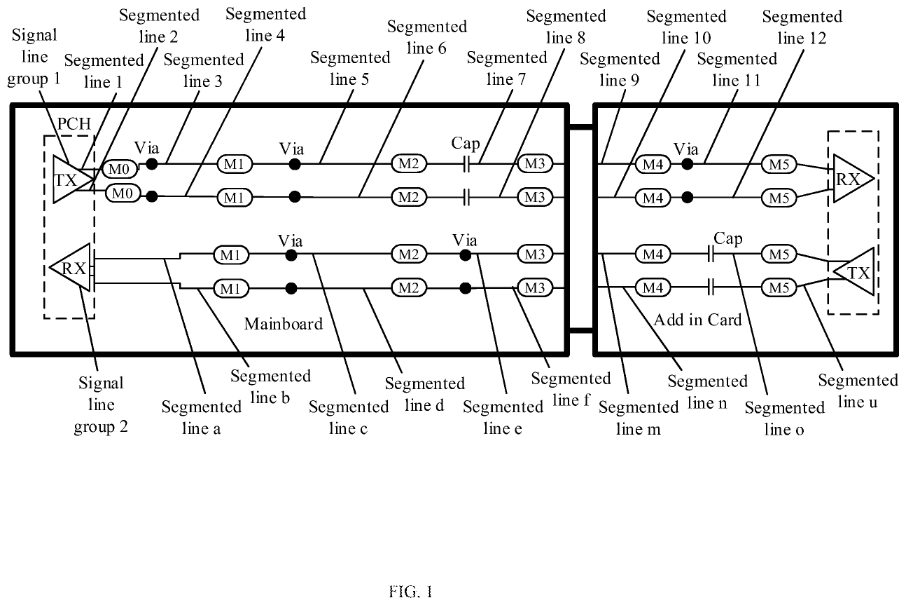

Referring to FIG. 1, the mainboard includes two signal line groups, namely, a signal line group 1 and a signal line group 2 starting from PCH. The signal line group 1 and the signal line group 2 after wiring are extended to a connection board Add in Card connected to the mainboard.

Referring to FIG. 1, the above-described signal line group 1 in the mainboard is taken for illustration, and the signal line group 1 includes two signal lines. One of the two signal lines passes through a via hole (i.e., Via) after passing through the TX port and the marking MO to form a segmented line 1, then passes through the next via hole (i.e., Via) after passing through the marking M1 to form a segmented line 3, then reaches one pole plate of a capacitor (i.e., Cap) after passing through the marking M2 to form a segmented line 5, forms a segmented line 7 by the other pole plate of the capacitor and the marking M3, then reaches the next via hole (i.e., Via) after passing through wire arrangement and the marking M4 to form a segmented line 9, and then reaches the receiving port RX after passing through the marking M5 to form a segmented line 11. The other signal line passes through a via hole (i.e., Via) after passing through the TX port and the marking MO to form a segmented line 2, then passes through the next via hole (i.e., Via) after passing through the marking M1 to form a segmented line 4, then reaches one pole plate of a capacitor (i.e., Cap) after passing through the marking M2 to form a segmented line 6, forms a segmented line 8 by the other pole plate of the capacitor and the marking M3, then reaches the next via hole (i.e. Via) after passing through wire arrangement and the marking M4 to form a segmented line 10, and then reaches the receiving port RX after passing through the marking M5 to form a segmented line 12.

Similarly, the segmented lines included in the two signal lines in the signal line group 2 are: a segmented line a, a segmented line b, a segmented line c, a segmented line d, a segmented line e, a segmented line f, a segmented line m, a segmented line n, a segmented line o, and a segmented line u, respectively.

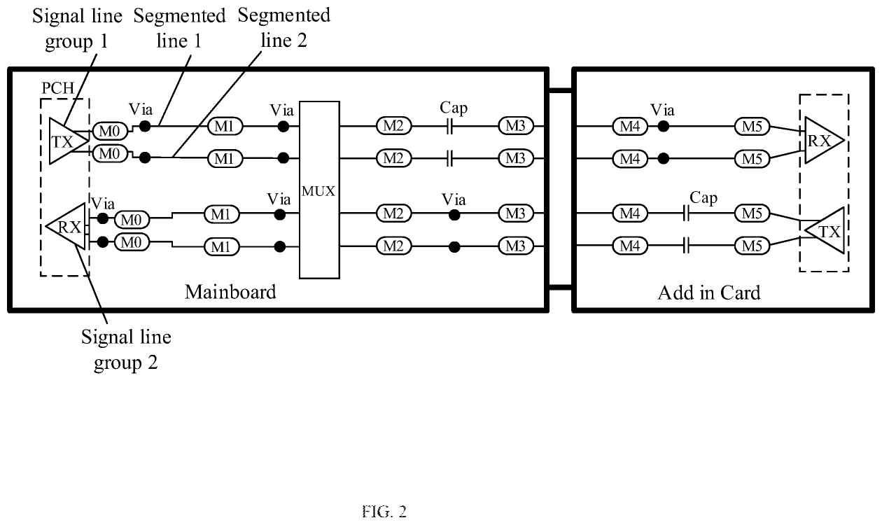

In addition, referring to FIG. 2, when the signal line group passes through a large processing chip, e.g., the processing chip MUX, in order to facilitate accurate detection for the signal line group, preferably, the signal lines at different ends (e.g., an input end and an output end) of the processing chip MUX are regarded as different signal line groups, so as to avoid that the processing chip truncates the signal lines, which has an effect on the detection.

The above signal line group 1 (or signal line group 2) is drawn in the drawing software as shown in FIG. 3. FIG. 3 is only a partially drawn schematic diagram of the signal line group 1 (or signal line group 2). It can be seen from the figure, the two signal lines included in the signal line group 1 (or signal line group 2) are routed in different layers of the printed circuit board (PCB) after passing through the via holes. Usually, the wiring lengths of signal lines respectively in different layers of the PCB are also different, i.e., the lengths of the segmented lines are different. After the signal line group 1 (or signal line group 2) is drawn in the drawing software, the signal line group needs to be detected to confirm that the signal line group is drawn correctly. The signal line group must be drawn correctly in order to make the circuit board made have the corresponding electrical characteristics.

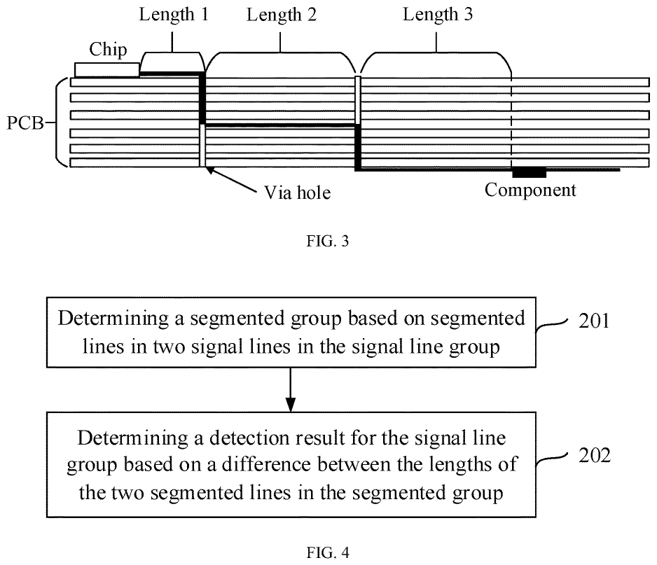

The following is a specific description of the process of detecting the signal line group. Referring to FIG. 4, in embodiments of the present disclosure, a specific process of detecting the signal line group is as follows.

Step 201: segmented groups are determined based on segmented lines in two signal lines in the signal line group; each of the segmented groups includes two segmented lines; the two segmented lines belong to different signal lines; and the two signal lines are configured to transmit two signals having the same amplitude and opposite phases.

In the process of detecting the signal line group, the length of each of segmented lines included in the signal line group is first detected. It should be noted that the length of each of the segmented lines in the segmented group is automatically read from the drawing software, and the drawing software is configured to draw the signal line group in a printed circuit board.

In the embodiments of the present disclosure, the length of each segmented line in each segmented group is automatically read from the drawing software by an automatic reading tool. The automatic reading tool is pre-developed through the Skill language. In order to record the respective lengths, preferably, the above read lengths are stored to a pre-designated location.

In order to facilitate the comparison of certain lengths (length 1, length 2 or length 3) corresponding to two segmented lines to determine whether to meet the requirements, in the implementation process, the segmented groups are first determined based on the segmented lines in the two signal lines included in the signal line group. Each segmented group includes two segmented lines, but the two segmented lines included belong to different signal lines. When the signal line is truncated into N segmented lines, the number of the above segmented groups is N.

The above length 1 is taken as an example for illustration, i.e., the two segmented lines corresponding to the length 1. When the signal lines are arranged horizontally, the segmented group includes the upper and lower segmented lines corresponding to the length 1. When the signal lines are arranged vertically, the segmented group includes the left and right segmented lines corresponding to the length 1. It should be noted that although the segmented group is labeled length 1 in FIG. 3, in fact, the lengths of the two segmented lines in the segmented group are not necessarily the length 1, and the lengths of the two segmented lines need to be determined through further comparisons of the lengths of the two segmented lines.

Usually, the above-described drawing software is used for drawing the signal line groups in the printed circuit board, because the PCB is converted from a schematic diagram with electrical properties. In order to facilitate the practical application of the circuit boards made subsequently, the above-described PCBs may be provided with via holes and the like, so that the electrical wires corresponding to the schematic diagram can be arranged in multiple layers in the PCBs, thereby reducing the volume of the circuit boards occupied in practical application. The segmented lines in this application are formed in the process of the electrical wires passing through via holes, components (e.g., capacitors, resistors, inductors and the like), etc., and the name of the aforementioned drawing software is not specifically limited herein.

In the implementation process, in order to determine which segmented lines in the signal line group belong to the same segmented group, the following mode is used: based on names of the signal lines corresponding to any two segmented lines and signal directions of signals in the signal lines, it is determined whether the two segmented lines belong to the same one segmented group.

The determining whether the two segmented lines belong to the same segmented group based on names of the signal lines corresponding to any two segmented lines and signal directions of signals in the signal lines, specifically includes the following.
[1] The signal lines corresponding to any two segmented lines in the drawing software are determined.

In order to determine which two segmented lines belong to the same one segmented group, in the implementation process, the signal lines corresponding to any two segmented lines respectively in the drawing software are first determined.

Because the corresponding electrical wires of the signal lines in the PCB are arbitrary, in order to identify each segmented line of the signal lines, in the embodiments of the present disclosure, the segmented lines are named according to the via holes and components, etc., through which the segmented lines pass. For example, the name 1 of the segmented line 1 is PICE_SSD_RXA0_P, the name 2 of the segmented line 2 is PICE_SSD_RXA0_N, the name 3 of the segmented line 3 is PICE_SSD_RXA0_N, and the name 4 of the segment line 4 is PICE_SSD_TXA0_N.

Considering that the segmented lines in the same one segmented group pass through the same via holes and components, etc., but belong to different signal lines, it can be determined that which segmented lines are segmented lines in the same one segmented group by the prefixes of the names in the above example, and which segmented lines belong to different signal lines by the suffixes of the names in the above example.
[2] In a case that the names of the signal lines corresponding to any two segmented lines are the same, and the signals of any two segmented lines have the same signal direction in the signal lines, it is determined that the any two segmented lines belong to the same one segmented group.

Considering that some components may be connected to a plurality of other components at the same time, there may be a plurality of branches under the signal line of the same name. In view of this, in the process of determining the segmented group, it is also necessary to combine the signal directions of the signals of the two segmented lines in the signal lines to make a comprehensive determination. That is, in the case of determining that the names of the signal lines corresponding to any two segmented lines are the same, it is further determined whether the signal directions of the signals of any two segmented lines in the signal lines are the same. If the signal directions are also the same, it is determined that the any two segmented lines belong to the same one segmented group.

Step 202: based on a difference between the lengths of the two segmented lines in the segmented group, a detection result for the signal line group is determined.

In the implementation process, the above lengths involve two aspects: the segmented length and a sum of lengths. That is, on one hand, it is necessary to whether the lengths of the segmented lines in the segmented group meet the requirements, and on the other hand, it is necessary to detect the sum of the lengths of signal lines in the signal line group. Typically, two signal lines are used for transmitting two signals having the same amplitude and opposite phases, i.e., the signal line group is a differential signal line group.

On one hand, the determining a detection result for the signal line group based on a difference between lengths of the two segmented lines in the segmented group, includes: determining that the segmented detection result for the signal line group is qualified in a case that the difference between the lengths of the two segmented lines in each of the segmented groups is less than a corresponding length threshold.

In the specific implementation process, after obtaining the lengths of the two segmented lines in any one of the segmented groups, a difference between the two lengths obtained above is determined, and the determined difference is compared with a preset length threshold corresponding to the segmented group. It is determined that the detection result for the segmented group is qualified if the difference is less than the length threshold, for example, the length threshold is 5 mils. It is determined that the segmented detection result for the signal line group is qualified when the detection results of all of the segmented groups in the signal line group are qualified.

It should be added that, since the position of each segmented group in the printed circuit board is uncertain, i.e., the segmented groups are in the same one layer or different layers of the printed circuit board, in order to accurately determine each segmented group, in the embodiments of the present disclosure, different length thresholds are set for different segmented groups. Specifically, the length thresholds corresponding to the two segmented lines in the segmented groups in different layers of the printed circuit board have different values. Typically, the above length thresholds are in the range of 5 mil to 10 mil.

On the other hand, the determining a detection result for the signal line group based on a difference between lengths of the two segmented lines in the segmented group, includes: in a case that a sum of lengths of the segmented lines belonging to the same signal line is less than a preset sum-of-lengths threshold, and a difference between the sums of lengths belonging to the same signal line group is less than a total length threshold, determining that the total length detection result for the signal line group is qualified.

It is to be noted that the above sum of lengths is the sum of the lengths of the signal line from an initial endpoint to a termination endpoint, i.e., each segmented line of each signal line is one segment, and the length of the segmented line is the length of a segment of the signal line that is truncated after passing through a certain component or a certain via hole, referring to the length 1, the length 2, the length 3 and the like in FIG. 3.

In the implementation process, for any one of the signal lines in the signal line group, it is first detected whether the total length (i.e., the sum of the lengths) is less than a preset sum-of-lengths threshold. In order to calculate the sum of the lengths, the segmented lines belonging to the same signal line are first determined, and the lengths of the segmented lines are added together to obtain the sum of the lengths; and afterward, it is determined whether the sum of the lengths is less than a preset sum-of-lengths threshold. Only when the sum of lengths is less than the preset sum-of-lengths threshold, is it determined that the sum of lengths of the signal line is qualified.

On the basis of the sum of lengths of the signal line being qualified, it is further determined that the difference between the sums of lengths belonging to the same signal line group is less than the total length threshold. In the implementation process, for the two signal lines in the signal line group, after the sum of lengths of each of the two signal lines is calculated and on the basis of the sum of lengths each being qualified, the difference between the sums of lengths is further calculated. When the difference is less than the preset total length threshold, it is determined that the total length detection result for the signal line group is qualified.

Furthermore, in the process of detecting the signal line group, in addition to detecting the lengths of the two signal lines in the signal line group, it is also necessary to detect the electrical connection performance of each signal line.

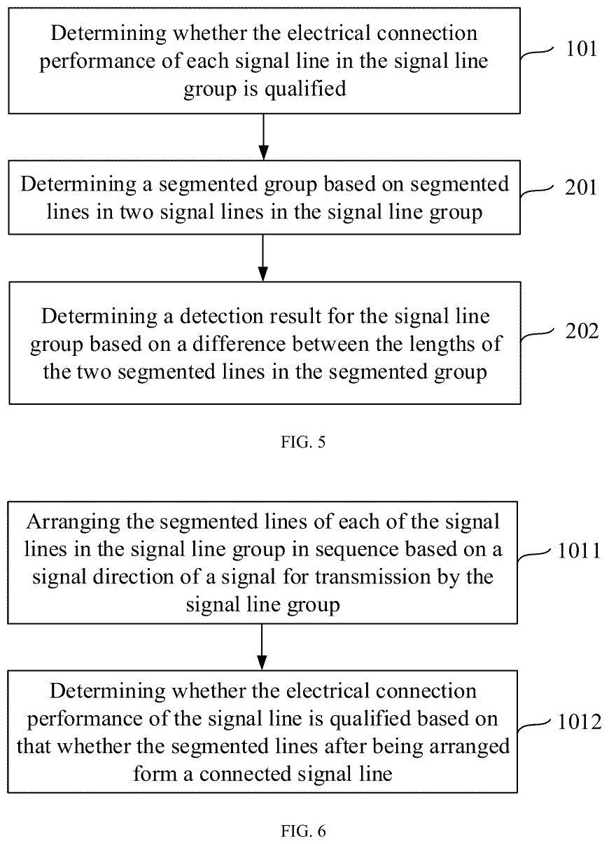

In the implementation process, before determining the lengths of the two segmented lines in the segmented group, as shown in FIG. 5, the method further includes the following: step 101: it is determined whether the electrical connection performance of each signal line in the signal line group is qualified.

Considering that the two signal lines in the signal line group are electrical connection lines for connecting components and via holes, etc., in the drawing software, in order to avoid the occurrence of ineffective electrical connection of the signal lines due to false connection, missed connection and the like, in the implementation process, it is necessary to detect whether the electrical connection performance of each of the two signal lines is qualified.

Referring to FIG. 6, the determining whether the electrical connection performance of each of the signal lines in the signal line group is qualified, includes the following: step 1011: the segmented lines of each of the signal lines in the signal line group are arranged in sequence based on a signal direction of a signal for transmission by the signal line group.

Since the signal line group drawn in the drawing software is used for transmitting a signal from an initial endpoint to a termination endpoint, i.e., the signal line group is drawn in accordance with the signal direction. After the signal line group is segmented by a component or via hole, two coordinates will be generated at the corresponding component or via hole, but the two coordinates belong to different segmented lines. That is, the coordinates of the endpoints of the two segmented lines that are adjacent to each other should be the same, and the coordinates of the connected endpoints should be extended sequentially in accordance with the signal direction of the signal.

Based on this, in the process of determining whether the electrical connection performance of the signal line is qualified, it is necessary to determine one by one whether the segmented lines of each signal line in the signal line group can be arranged in sequence.

Step 1012: it is determined whether the electrical connection performance of the signal line is qualified based on that whether the segmented lines after being arranged form a connected signal line.

After arranging the segmented lines of each signal line in the signal line group in sequence, if the segmented lines of the same one signal line can form one connected signal line, it is determined that the electrical connection performance of the signal line is qualified; and if the segmented lines of the same one signal line cannot form one connected signal line, it is determined that the electrical connection performance of the signal line is not qualified.

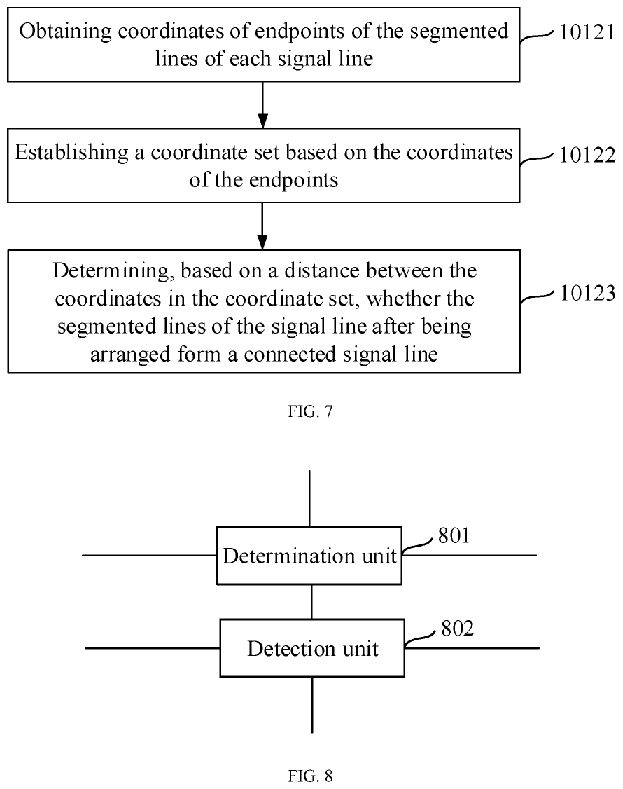

Referring to FIG. 7, as shown in FIG. 7, it is determined whether the segmented lines of each signal line form a connected signal line in the following mode.

Step 10121: coordinates of endpoints of the segmented lines of each signal line are obtained, where the coordinates do not include coordinates of the initial endpoint and the termination endpoint of the signal line, and the endpoints are configured to indicate connection points of electrical symbols corresponding to the segmented lines in the printed circuit board.

In order to conveniently and accurately determine the connectivity of the signal line, in the embodiments of the present disclosure, the determination is made based on the coordinates of the endpoints of the segmented lines of the same one signal line. The endpoints are configured to indicate the connection points, e.g., pins of a resistor, pole plates of a capacitor, via holes, and the like, of the electrical symbols corresponding to segmented lines in the printed circuit board.

The determination of the connectivity of the signal line is explained by the following example. For example, for two segmented lines starting from an initial endpoint, the coordinates of the right endpoint of the first segmented line are to the right with respect to the coordinates of the left endpoint of the first segmented line, the coordinates of the right endpoint of the second segmented line are also to the right with respect to the coordinates of the left endpoint of the second segmented line, and the coordinates of the right endpoint of the first segmented line are the same as the coordinates of the left endpoint of the second segmented line. That is, it is determined that the coordinates of the endpoints of the above two segmented lines can be arranged in sequence, and so on, until all segmented lines are determined to be able to be arranged in sequence, then it can be determined that the signal line is a connected signal line.

In the implementation process, the coordinates of the endpoints of segmented lines of each signal line are first obtained in the drawing software. Usually, the coordinates are xy coordinates in a two-dimensional coordinate system. Moreover, considering that the coordinates of the initial endpoint and the termination endpoint of the signal line are isolated points, and the initial endpoint and the termination endpoint are only isolated input (or output) points during the signal transmission process, the initial endpoint and the termination endpoint are not taken into account during the process of determining the connectivity of the signal line.

Step 10122: based on the coordinates of the endpoints, a coordinate set is established.

In the implementation process, after obtaining the coordinates of the endpoints of the segmented lines, the obtained coordinates are added to the coordinate set, i.e., the determination of the connectivity of the signal line is converted into the processing of the coordinates in the coordinate set.

Step 10123: it is determined whether the segmented lines of the signal line after being arranged form a connected signal line, based on a distance between the coordinates in the coordinate set.

After determining the coordinate set, the distance between any two coordinates is determined separately. Based on this, it is determined whether a connected signal line is formed by arranging the segmented lines by the following two cases.

The first case: the determining whether the segmented lines of the signal line after being arranged form a connected signal line based on a distance between the coordinates in the coordinate set, includes the following.
[1] Matching coordinates whose distance from target coordinates is not greater than a coordinate threshold are searched for in the coordinate set, where the target coordinates are coordinates of any of the endpoints in the coordinate set.

Since coordinates in the coordinate set are a collection of the coordinates of the endpoints of all segmented lines of the signal line, in order to determine the connectivity of the signal, in the implementation process, the coordinates of any endpoint in the coordinate set are referred to as the target coordinates, i.e., all endpoints in the coordinate set are respectively taken as the target coordinates. Afterwards, matching coordinates corresponding to the target coordinates are searched for in the coordinate set. The matching coordinates are the coordinates of the endpoint of another segmented line whose distance from the target coordinates is not greater than a coordinate threshold. Considering the error of acquiring coordinates, etc., usually, two coordinates within the coordinate threshold are determined as the same coordinates.
[2] Based on that the matching coordinates exist or no matching coordinates exist, it is determined whether the segmented lines of the signal line after being arranged form a connected signal line.

In the implementation process, if it is determined that all the target coordinates have corresponding matching coordinates in the coordinate set, then the segmented lines can be connected by the target coordinates and the matching coordinates which are the same coordinates, and it is then determined that the segmented lines of the signal line after being arranged can form a connected signal line.

If it is determined that one or more target coordinates do not have corresponding matching coordinates in the coordinate set, then the segmented lines corresponding to the one or more target coordinates cannot be connected by the target coordinates and the matching coordinates which are the same coordinates, so that the signal line is disconnected, so as to further determine that the segmented lines of the signal line after being arranged cannot form a connected signal line.

The second case: the searching in the coordinate set for matching coordinates whose distance from target coordinates is not greater than a coordinate threshold, includes the following.
(1) The coordinates in the coordinate set are divided into a plurality of subsets of different types based on the endpoints in the coordinate set.

Considering that the large number of signal line groups in the printed circuit board, the coordinates of the endpoints of all segmented lines are put into a coordinate set, and the data volume of the coordinate set is large, so that the subsequent process of searching for the coordinates is cumbersome.

Based on this, in the implementation process, considering that the endpoints are connection points indicating the electrical symbols corresponding to segmented lines in the printed circuit board, and the electrical symbols include via holes, pins of components and the like, the coordinates in the coordinate set are divided into a plurality of subsets of different types according to the types of the electrical symbols of endpoints in the coordinate set, etc.

After dividing the coordinate set into a plurality of subsets of different types, the subsets are used as the objects for searching in the process of searching for matching coordinates, thereby effectively improving the efficiency of searching.

In embodiments of the present disclosure, the plurality of subsets of different types include at least a pin subset, a via-hole subset, a surface-layer line subset and an inner-layer line subset.

The above pin subset usually includes a collection of segmented lines formed by pins of various components. The above via-hole subset usually refers to a collection of segmented lines formed by via holes of the printed circuit board. The above surface-layer line subset usually includes a collection of segmented lines formed by surface wiring of the printed circuit board. The above inner-layer line subset usually includes a collection of segmented lines formed by non-surface wiring of the printed circuit board. The above-described coordinate set is divided into the pin subset, the via-hole subset, the surface-layer line subset, and the inner-layer line subset.

It should be noted that the division of the above subsets can also be set flexibly according to a size of the printed circuit board, the number of signal line groups, etc.
(2) The matching coordinates whose distance from the target coordinates is not greater than the coordinate threshold is searched for in the subset of the same type.

In order to quickly and accurately find the matching coordinates, in the implementation process, the matching coordinates for the target coordinates are first searched for in the subset of the same type, i.e., the subset of one type is first determined. Any one of the coordinates in the subset of the one type as the target coordinates.

For all target coordinates, if matching coordinates whose distance from the target coordinates is not greater than the coordinate threshold can be found in this subset, it means that the segmented lines corresponding to this subset is connected. For one or more target coordinates, if matching coordinates whose distance from the target coordinates is not greater than the coordinate threshold cannot be found in this subset, it means that the segmented lines corresponding to this subset of the same type is not connected.
(3) In a case that no matching coordinates are found in the subset of the same type, the matching coordinates whose distance from the target coordinates is not greater than the coordinate threshold are searched for in the subsets of other types.

Considering that some segmented lines are at different types of endpoints, in the implementation process, when no matching coordinates can be found in the subset of the same type, matching coordinates continue to be searched for in the subsets of other types. That is, based on that the matching coordinates can be found in the above subset of the same type, the matching coordinates whose distance from the target coordinates is not greater than the coordinate threshold continue to be searched for in the subsets of other types. The subsets of other types and the subset of the same type have different types herein.

For all target coordinates, if matching coordinates whose distance from the target coordinates is not greater than the coordinate threshold can be found in the subsets of other types, it means that the segmented lines corresponding to the coordinates are connected. For one or more target coordinates, if matching coordinates whose distance from the target coordinates is not greater than the coordinate threshold cannot be found in the subsets of other types, it means that the segmented lines corresponding to the subset of the same type is not connected.

Corresponding to the first case and the second case described above, the determining, based on that the matching coordinates exist or no matching coordinates exist, whether the segmented lines of the signal line after being arranged form a connected signal line, includes the following.
Situation 1: in a case that the matching coordinates exist, it is determined that the segmented lines of the signal line after being arranged form a connected signal line.

In the implementation process, whether through the coordinate set or the various subsets, after determining that all target coordinates have corresponding matching coordinates, it is determined that the segmented lines of the signal line after being arranged can form a connected signal line, and then it is determined that the electrical connection performance of the signal line is qualified.
Situation 2: in a case that no matching coordinates exist, it is determined that the segmented lines of the signal line after being arranged do not form a connected signal line.

In the implementation process, after determining that one or more target coordinates do not have corresponding matching coordinates whether through the coordinate set or the various subsets, it is determined that the segmented lines of the signal line after being arranged cannot form a connected signal line, and then it is determined that the electrical connection performance of the signal line is unqualified.

After determining that the electrical connection performance of two signal lines of the signal line group is qualified, and the associated lengths of the signal line group including the two signal lines are detected to be qualified, it is determined that the signal line group is drawn correctly.

Based on the same inventive concept, referring to FIG. 8, embodiments of the present disclosure provide a device for detecting a signal line group, including: a determination unit 801, configured to determine segmented groups based on segmented lines in two signal lines in the signal line group; where each of the segmented groups includes two segmented lines; the two segmented lines belong to different signal lines; and the two signal lines are configured to transmit two signals having the same amplitude and opposite phases; and a detection unit 802, configured to determine a detection result for the signal line group based on a difference between lengths of the two segmented lines in the segmented group.

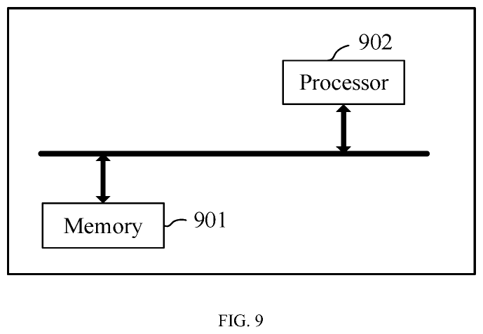

Based on the same inventive conception, referring to FIG. 9, embodiments of the present disclosure provide a device for detecting a signal line group, including: a memory 901, configured to store executable instructions; and a processor 902, configured to read and execute the executable instructions stored in the memory, to implement any one of the above-described methods for detecting a signal line group.

Based on the same inventive concept, embodiments of the present disclosure provide a computer-readable storage medium, and instructions in the storage medium, when executed by a processor, cause the processor to execute the method described in any one of the above-described methods for detecting a signal line group.

In summary, embodiments of the present disclosure provide a method and device for detecting a signal line group, and a medium. The method is as follows: segmented groups are determined based on segmented lines in two signal lines in the signal line group; usually, each signal line in the signal line group includes a plurality of segmented lines, so that there are a plurality of segmented groups; each of the segmented groups includes two segmented lines, the two segmented lines belong to different signal lines, and the two signal lines are configured to transmit two signals having the same amplitude and opposite phases; and a detection result for the signal line group is determined based on a difference between lengths of the two segmented lines in the segmented group, i.e., whether the detection result for the signal line group is qualified is quickly and accurately determined by comparing the differences corresponding to the segmented groups.

It should be appreciated by those skilled in the art that embodiments of the present disclosure may be provided as methods, systems, or computer program product systems. Thus, the present disclosure may take the form of a fully hardware embodiment, a fully software embodiment, or an embodiment that combines software and hardware aspects. Further, the present disclosure may take the form of a computer program product system implemented on one or more computer-usable storage media (including, but not limited to, a disk memory, a compact disc read-only memory (CD-ROM), an optical memory, and the like) that contain computer-usable program codes therein.

The present disclosure is described with reference to flowcharts and/or block diagrams of methods, devices (systems), and computer program product systems according to the present disclosure. It is to be understood that computer program instructions may implement each of the processes and/or blocks in the flowchart and/or block diagram, and the combination of processes and/or blocks in the flowchart and/or block diagram. These computer program instructions may be provided to a processor of a general-purpose computer, a special-purpose computer, an embedded processor, or other programmable data-processing device to produce a machine, such that the instructions executed by the processor of the computer or other programmable data-processing device produce a device for carrying out the functions specified in one or more processes of the flowchart and/or one or more blocks of the block diagram.

These computer program instructions may also be stored in computer-readable memory capable of directing the computer or other programmable data processing device to operate in a particular manner, such that the instructions stored in the computer-readable memory produce an article of manufacture including an instruction device that implements the functions specified in one or more processes of the flowchart and/or one or more blocks of the block diagram.

These computer program instructions may also be loaded onto a computer or other programmable data processing device, such that a series of operational steps are performed on the computer or other programmable device to produce computer-implemented processing, such that the instructions executed on the computer or other programmable device provide steps for implementing the functions specified in one or more processes of the flowchart and/or one or more blocks of the block diagram.

Obviously, those skilled in the art can make various changes and variations to the present disclosure without departing from the spirit and scope of the present disclosure. Thus, if these modifications and variations of the present disclosure are within the scope of the claims of the present disclosure and their technical equivalents, the present disclosure is intended to encompass such modifications and variations.

1. A method for detecting a signal line group, comprising:
determining segmented groups based on segmented lines in two signal lines in the signal line group; wherein each of the segmented groups comprises two segmented lines; the two segmented lines belong to different signal lines; and the two signal lines are configured to transmit two signals having the same amplitude and opposite phases; and
determining a detection result for the signal line group based on a difference between lengths of the two segmented lines in the segmented group.

2. The method according to claim 1, wherein the determining a detection result for the signal line group based on a difference between lengths of the two segmented lines in the segmented group, comprises:
determining that the segmented detection result for the signal line group is qualified in a case that the difference between the lengths of the two segmented lines in each of the segmented groups is less than a corresponding length threshold.

3. The method according to claim 1, wherein the determining a detection result for the signal line group based on a difference between lengths of the two segmented lines in the segmented group, comprises:
in a case that a sum of lengths of the segmented lines belonging to the same one signal line is less than a preset sum-of-lengths threshold, and a difference between the sums of lengths belonging to the same one signal line group is less than a total length threshold, determining that a total length detection result for the signal line group is qualified.

4. The method according to claim 2, wherein the segmented groups are in the same one layer or different layers of a printed circuit board, and length thresholds corresponding to two segmented lines in segmented groups in different layers of the printed circuit board have different values.

5. The method according to claim 1, wherein the length of each of the segmented lines in the segmented group is automatically read from a drawing software, and the drawing software is configured to draw the signal line group in a printed circuit board.

6. The method according to claim 5, wherein whether two segmented lines belong to the same one segmented group is determined by:
determining, based on names of the signal lines corresponding to any two segmented lines and the signal directions of signals in the signal lines, whether the two segmented lines belong to the same one segmented group.

7. The method according to claim 6, wherein the determining, based on names of the signal lines corresponding to any two segmented lines and the signal directions of signals in the signal lines, whether the two segmented lines belong to the same one segmented group, comprises:
determining the signal lines corresponding to any two segmented lines in the drawing software; and
in a case that the names of the signal lines corresponding to any two segmented lines are the same, and the signals of any two segmented lines have the same signal direction in the signal lines, determining that the any two segmented lines belong to the same one segmented group.

8. The method according to claim 1, wherein before determining a detection result for the signal line group based on a difference between lengths of the two segmented lines in the segmented group, the method further comprises:
determining whether an electrical connection performance of each of the signal lines in the signal line group is qualified.

9. The method according to claim 8, wherein the determining whether an electrical connection performance of each of the signal lines in the signal line group is qualified, comprises:
arranging the segmented lines of each of the signal lines in the signal line group in sequence based on a signal direction of a signal for transmission by the signal line group; and
determining whether the electrical connection performance of the signal line is qualified based on that whether the segmented lines after being arranged form a connected signal line.

10. The method according to claim 9, wherein whether the segmented lines of each of the signal lines form a connected signal line is determined by:
obtaining coordinates of endpoints of the segmented lines of each of the signal lines, wherein the endpoints are configured to indicate connection points of electrical symbols corresponding to the segmented lines in the printed circuit board;
establishing a coordinate set based on the coordinates of the endpoints; and
determining, based on a distance between the coordinates in the coordinate set, whether the segmented lines of the signal line after being arranged form a connected signal line.

11. The method according to claim 10, wherein the determining, based on a distance between the coordinates in the coordinate set, whether the segmented lines of the signal line after being arranged form a connected signal line, comprises:
searching in the coordinate set for matching coordinates whose distance from target coordinates is not greater than a coordinate threshold, wherein the target coordinates are coordinates of any of the endpoints in the coordinate set; and
determining, based on that the matching coordinates exist or no matching coordinates exist, whether the segmented lines of the signal line after being arranged form a connected signal line.

12. The method according to claim 11, wherein the determining, based on that the matching coordinates exist no matching coordinates exist, whether the segmented lines of the signal line after being arranged form a connected signal line, comprises:
in a case that the matching coordinates exist, determining the segmented lines of the signal line after being arranged form a connected signal line; and
in a case that no matching coordinates exist, determining the segmented lines of the signal line after being arranged do not form a connected signal line.

13. The method according to claim 12, wherein the searching in the coordinate set for matching coordinates whose distance from target coordinates is not greater than a coordinate threshold, comprises:
dividing the coordinates in the coordinate set into a plurality of subsets of different types based on the endpoints in the coordinate set;
searching in the subset of the same type for the matching coordinates whose distance from the target coordinates is not greater than the coordinate threshold; and
in a case that no matching coordinates are found in the subset of the same type, searching in the subsets of other types for the matching coordinates whose distance from the target coordinates is not greater than the coordinate threshold.

14. The method according to claim 13, wherein the plurality of subsets of different types comprise at least a pin subset, a via-hole subset, a surface-layer line subset and an inner-layer line subset.

15. A device for detecting a signal line group, comprising:
a memory, configured to store executable instructions; and
a processor, configured to read and execute the executable instructions stored in the memory to implement the method according to claim 1.

16. A computer-readable storage medium, wherein instructions in the storage medium, when executed by a processor, cause the processor to execute the method according to claim 1.

17. The method according to claim 2, wherein before determining a detection result for the signal line group based on a difference between lengths of the two segmented lines in the segmented group, the method further comprises:
determining whether an electrical connection performance of each of the signal lines in the signal line group is qualified.

18. The method according to claim 3, wherein before determining a detection result for the signal line group based on a difference between lengths of the two segmented lines in the segmented group, the method further comprises:
determining whether an electrical connection performance of each of the signal lines in the signal line group is qualified.

19. The method according to claim 4, wherein before determining a detection result for the signal line group based on a difference between lengths of the two segmented lines in the segmented group, the method further comprises:
determining whether an electrical connection performance of each of the signal lines in the signal line group is qualified.

20. The method according to claim 5, wherein before determining a detection result for the signal line group based on a difference between lengths of the two segmented lines in the segmented group, the method further comprises:
determining whether an electrical connection performance of each of the signal lines in the signal line group is qualified.
